(19) United States
(12) Patent Application Publication
(10) Pub. No.: US 2002/0048297 A1
(43) Pub. Date: Apr. 25, 2002

(54) Semiconductor laser module and raman amplifier employing the same

(75) Inventors: Yuichiro Irie, Tokyo (JP); Jun Miyokawa, Tokyo (JP); Takeshi Aikiyo, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Tokyo (JP)

(21) Appl. No.: 09/981,849

(22) Filed: Oct. 19, 2001

(30) Foreign Application Priority Data
Oct. 20, 2000 (JP) 2000-321378

(51) Int. Cl. H01S 5/024

(52) U.S. Cl. 372/36

(57) ABSTRACT

A semiconductor laser diode module according to the present invention is of high power, low noise, good wavelength stability and high reliability irrespective of the temperature change of a service environment. As shown in FIG. 1A, a thermo-electric-module (25) is mounted on the bottom plate (26) of a package (27), and a base (2) is mounted on the thermo-electric-module (25). Mounted on the base (2) area laser diode (1), a first optical fiber (4) which feeds laser light emitted from one end (31) of the laser diode (1), back to the laser diode (1), and fixation means (6), (7) for supporting the first optical fiber (4) at the positions of two points in the lengthwise direction of this fiber (4). A second optical fiber (13) which receives and transmits the laser light, is disposed on the side of the other end (30) of the laser diode (1). An axis part (33) which connects the laser light emitting face of the laser diode (1) at one end (31) thereof and the laser light receiving end of the optical fiber (4), is located on the end side of the thermo-electric-module (25) with respect to the central part (C) thereof in the direction of the optic axis of the laser diode (1).

### BACKGROUND OF THE INVENTION

Owing to the progress of the information-oriented society, the quantity of transmitting data of communication or information tends to increase rapidly. With such increase of data, wavelength division multiplexing (WDM) transmission system has been extensively accepted in the field of communication, and now is the times of the WDM transmission. The WDM technology optical transmission system can transmit lights of a plurality of wavelengths through a single optical fiber. Therefore, the WDM transmission system is an optical transmission method suited to high capacity and high bit-rate transmission. At present, the WDM transmission technology is actively studied.

The transmission band of the WDM transmission presently studied is a wavelength band of 1.55 μm. The wavelength band of 1.55 μm is the gain band of erbium-doped optical fiber (EDF) amplifier. In order to more widen the band of the WDM transmission, however, Raman amplification is highly expectative.

The Raman amplification is an optical amplification method which utilizes the fact that, when intense pumping light is caused to enter an optical fiber, gain appears in a region of wavelengths about 100 nm longer than that of the pumping light, owing to induced Raman scattering. When signal light in the wavelength region having the gain is caused to enter the optical fiber in such a pumped state, there arises the phenomenon that the signal light is amplified.

For the Raman amplification, accordingly, an optical fiber in operation can be used as an amplifying medium without especially laying an EDF. Moreover, the Raman amplification can attain the amplification gain at any desired wavelength. It is therefore permitted by utilizing the Raman amplification to widen the band of signal lights in the WDM transmission and to increase the number of channels.

In case of using the (ordinary existing) optical fiber for communications, however, the gain of the Raman amplification is as low as about 3 dB for a pumping light input of 100 mW. Therefore, intense pumping light needs to combined two polarized lights to obtain high power light. In general, it is studied to endow the pumping light with a power on the order of 500 mW-1 W in total by the polarization combination/wavelength multiplex.

Besides, in the Raman amplification, an amplifying process occurs so fast that fluctuation in the intensity of pumping light results in fluctuation in the Raman gain. The fluctuation in the Raman gain directly gives fluctuation in the intensity of signal light. In the Raman amplification, therefore, it is important to reduce the noise of the pumping light.

In order to apply the Raman amplification to the WDM transmission, accordingly, a pumping light source for a Raman amplifier needs to be a light source whose noise is low, which produces a high power of, for example, at least 300 mW and which exhibits a good wavelength stability. It becomes very important to develop a semiconductor laser diode module for the pumping light source having such properties.

The semiconductor laser diode module is a device in which laser light from a semiconductor laser diode (laser diode) is optically coupled with an optical fiber on an optical transmission side. The semiconductor laser diode module is applied, not only as the pumping light source as stated above, but also as a light source for signal light. Various constructions have been proposed for such semiconductor laser diode modules. FIG. 6 shows the construction of the essential portions of an example of a semiconductor laser diode module. The semiconductor laser diode module employs fiber Bragg grating technology in order to attain a good wavelength stability.

In the semiconductor laser diode module, a semiconductor laser diode 1, and a first optical fiber 4 optically coupled with the laser diode 1 are mounted over a base 2. The first optical fiber 4 is so arranged that the tip end of a fiber lens 14 formed on the fore end side of this optical fiber 4 confronts one end 31 of the laser diode 1.

The first optical fiber 4 is formed with a fiber grating 12 being a diffraction grating which reflects light of a Bragg certain set wavelength. This first optical fiber 4 feeds the light of the set wavelength among lights emitted from one end of the laser diode 1, back to the laser diode 1 by means of the fiber Bragg grating 12.

By the way, in this figure, numeral 22 indicates a heat sink. Besides, appropriate optical coupling means 32 which is usually a lens portion or the like is interposed between the other end 30 of the laser diode 1 and the connection end face of a second optical fiber 13.

In the semiconductor laser diode module, both the first optical fiber 4 and the second optical fiber 13 are concentered or made concentric with the laser diode 1. The laser lights emitted from one end 31 of the laser diode 1 are received by the first optical fiber 4, and the light of the set wavelength is fed back to the laser diode 1. While the light of the set wavelength is being fed back, emission light emitting from the other end 30 of the laser diode 1 is received by the second optical fiber 13. The light received by the second optical fiber 13 is transmitted within the second optical fiber 13 and is put into a desired use.

The structure as stated above wherein lasing is effected while the light of the set wavelength among the laser lights emitted from one end 31 of the laser diode 1 is being fed back to this laser diode 1, can shorten the spacing between the tip end of the first optical fiber 4 and the laser diode 1. Therefore, the lasing system can reduce the RIN (Relative Intensity Noise) of the semiconductor laser diode module.

Besides, in the semiconductor laser diode module shown in FIG. 6, the base 2 is mounted on a thermo-electric-module (not shown). During the use of the semiconductor laser diode module, the temperature of the laser diode 1 is measured by a thermistor (not shown) which is mounted on the heat sink in the vicinity of this laser diode 1. The thermo-electric-module is operated on the basis of the measured value so as to perform a control for keeping the temperature of the laser diode 1 constant.

### SUMMARY OF THE INVENTION

The present invention provides a semiconductor laser diode module and a Raman amplifier employing the semiconductor laser diode module.

A semiconductor laser diode module according to the present invention comprises:

a laser diode which emits laser lights;

a first optical fiber which is arranged on one end side of said laser diode in a state where it is optically coupled with said laser diode;

a second optical fiber which is arranged on the other end side of said laser diode in a state where it is optically coupled with said laser diode;

a base on which said laser diode and said first optical fiber are arranged and fixed;

a thermo-electric-module on which said base is mounted; and

a diffraction Bragg grating which is formed within said first optical fiber so as to feed the light of a set wavelength back to said laser diode;

wherein said laser diode and said first optical fiber are located relative to said thermo-electric-module so that a segment which connects a laser light emitting end face of said laser diode at one end thereof and a laser light receiving end of said first optical fiber may lie on an end side of said thermo-electric-module with respect to a central part thereof in an direction of an optic axis of said laser diode.

### BRIEF DESCRIPTION OF THE DRAWINGS

Exemplary embodiments of the invention will now be described in conjunction with drawings, in which:

FIG. 1A is an essential structure view showing the first embodiment of a semiconductor laser diode module according to the present invention;

FIG. 1B is an enlarged view of the coupling part between a laser diode and a first optical fiber in the first embodiment;

FIG. 2 is an essential structure view showing the second embodiment of the semiconductor laser diode module according to the present invention;

FIG. 3 is an essential structure view showing the third embodiment of the semiconductor laser diode module according to the present invention;

FIG. 4 is an essential structure view showing another embodiment of the semiconductor laser diode module according to the present invention;

FIG. 5 is an essential structure view showing still another embodiment of the semiconductor laser diode module according to the present invention; and

FIG. 6 is an explanatory view showing an example of a semiconductor laser diode module which has heretofore been proposed.

### Detailed Description

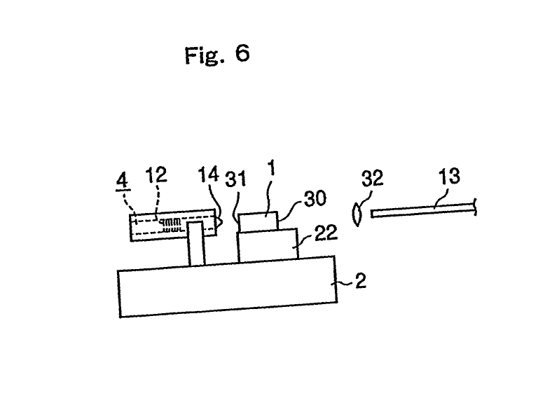

With the semiconductor laser diode module with the structure as shown in FIG. 6, when the driving state of the thermo-electric-module attendant upon an external temperature change has changed, this thermo-electric-module is distorted to consequently distort the base 2.

With the semiconductor laser diode module in the prior art, in arranging the laser diode 1 and the first optical fiber 4 over the base 2, where the coupling positions of the members 1 and 4 are set over the base 2 are not especially considered. In the prior-art semiconductor laser diode module, therefore, the positional deviation between the laser diode 1 and the first optical fiber 4 occurs under the influence of the distortion of the base 2.

The positional deviation of the first optical fiber 4 relative to the laser diode 1 incurs great lowering in the optical coupling efficiency between these members 1 and 4. The lowering in the optical coupling efficiency incurs a lower optical power and unstable wavelengths in the semiconductor laser diode module of the structure wherein the emission lights from the laser diode 1 are received by the first optical fiber 4 so as to feed back the light of the set wavelength. In the worst case, wavelength lock by the diffraction grating 12 formed in the first optical fiber 4 might pull out in the semiconductor laser diode module. Accordingly, the positional deviation of the first optical fiber 4 relative to the laser diode 1 is a serious problem.

In one aspect of a semiconductor laser diode module according to the present invention, a laser diode and an optical fiber, which receives laser lights from the laser diode and feeds the light of a set wavelength back to the laser diode, can be optically coupled at a high precision without regard to the distortion of a base. The semiconductor laser diode module of this structure is one of high reliability. Besides, one aspect of a Raman amplifier according to the present invention employs the semiconductor laser diode module as stated above, thereby to include a pumping light source whose noise is low, which produces a high power and which exhibits a good wavelength stability. Such a Raman amplifier is well suited to wavelength division multiplexing (WDM) transmission.

Now, embodiments of the present invention will be described with reference to the drawings. By the way, in the ensuing description of the embodiments, the same reference numerals will be respectively assigned to the portions of the same names as in the prior-art example, and they shall not be repeatedly explained.

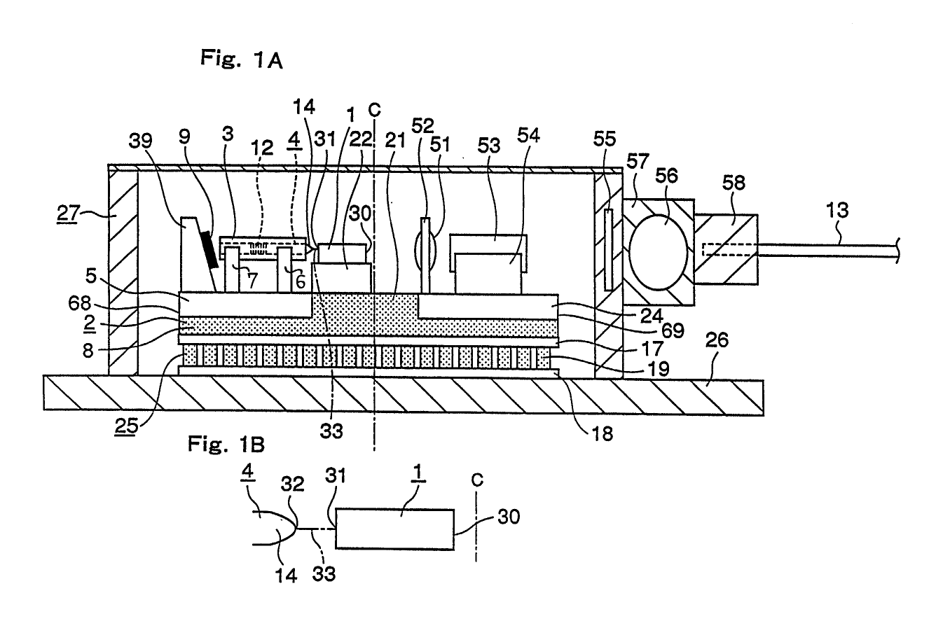

Referring to FIG. 1A, the first embodiment of a semiconductor laser diode module according to the present invention is shown by a sectional view. The semiconductor laser diode module of the first embodiment includes a package 27, in which a thermo-electric-module 25 is disposed. The thermo-electric-module 25 is mounted on the bottom plate 26 of the package 27. The bottom plate 26 of the package 27 is formed of “CuW20” or the like being a Cu-W alloy. The alloy CuW20 consists of 20% of Cu and 80% of W in terms of weight.

A base 2 is mounted on the thermo-electric-module 25. Disposed over the base 2 are a laser diode 1, and a first optical fiber 4 which is formed with a fiber Bragg grating 12. Both the ends 30, 31 of the laser diode 1 are respectively provided with anti reflection coatings. A fiber lens 14 is formed on the fore end side of the first optical fiber 4. The fiber lens 14 presents, for example, a spherical tip shape.

Using the fiber lens 14, the semiconductor laser diode module can shorten the distance between the laser diode 1 and the fiber Bragg grating 12. A resonance frequency of the semiconductor laser diode is determined in accordance with the distance between the laser diode 1 and the fiber Bragg grating 12. Since the first embodiment can shorten the distance between the members 1 and 12, it can move the resonance frequency onto a higher frequency side to apparently reduce RIN (Relative Intensity Noise) in a lower frequency region.

Incidentally, the shape of the fiber lens 14 is not especially restricted, but it can be appropriately set. The fiber lens 14 may be an anamorphic lens, for example, a well-known wedge-shaped lens, or it may well be any anamorphic lens other than the wedge-shaped lens. Of course, the optical coupling between the laser diode 1 and the first optical fiber 4 can also be effected by employing an optical system which is similar to a collimating lens 51 or a condensing lens 56 to be explained later.

The most important feature of the semiconductor laser diode module of the first embodiment is that an axis part 33 indicated in FIGS. 1A and 1B is located on the end side of the thermo-electric-module 25 with respect to the central part thereof (C in FIGS. 1A and 1B) in the direction of the optic axis of the laser diode 1. As shown in FIG. 1B, the axis part 33 is formed of a segment which connects the laser light emitting end face of the laser diode 1 at one end 31 thereof and the laser light receiving end 32 of the first optical fiber 4.

Besides, as shown in FIG. 1A, in the first embodiment, the first optical fiber 4 is supported by a sleeve 3 being optical fiber support means. In a state where the first optical fiber 4 is supported by the sleeve 3, it is fixed to the base 2 by fixation means 6, 7 which are located at a plurality of points (here, two points) in the lengthwise direction of this optical fiber 4. Further, a monitor photodiode 9 is disposed on the hind end side of the first optical fiber 4. The monitor photodiode 9 is fixed to a monitor photodiode fixture 39.

On the side of the other end 30 of the laser diode 1, the collimating lens 51, an isolator 53, a light transmission plate 55, the condensing lens 56 and a second optical fiber 13 are successively arranged in mutually spaced fashion. In this manner, in the first embodiment, the two lens portions (collimating lens 51, condensing lens 56) are disposed between the other end 30 of the laser diode 1 and the second optical fiber 13. The collimating lens 51 functions as the first lens portion which is located nearest to the laser diode 1.

Besides, the collimating lens 51 is held by a lens holder 52 and is mounted and fixed on the base 2. The isolator 53 is held by an isolator holder 54 and is mounted and fixed on the base 2. The light transmission plate 55 is formed of sapphire glass or the like, and has the function of sealing the package 27. The condensing lens 56 condenses light emitted from the laser diode 1, onto the side of one end of the second optical fiber 13. The condensing lens 56 is fixed to a lens holder 57. The second optical fiber 13 is held by a holder 58.

The thermo-electric-module 25 includes a base side plate member 17, a bottom plate side plate member 18, and a Peltier element 19 which is sandwiched in between the plate members 17 and 18. The base side plate member 17 and bottom plate side plate member 18 of the thermo-electric-module 25 are both formed of Al₂O₃.

In the first embodiment, the base 2 includes a laser diode mounting member 8 which is formed with a region for mounting the laser diode 1 (an LD bonding area) as indicated at numeral 21. Also, the base 2 includes a fixation means mounting member 5 on which the fixation means 6 and 7 are mounted. Further, the base 2 includes a holder mounting member 24 on which the lens holder 52 and the isolator holder 54 are mounted.

The laser diode mounting member 8 is formed of “CuW10” being a Cu-W alloy. The alloy CuW10 consists of 10% of Cu and 90% of W in terms of weight. The fixation means mounting member 5 and the holder mounting member 24 are formed of Covar being a Fe—Ni—Co alloy, stainless steel or the like. The laser diode mounting member 8, fixation means mounting member 5 and holder mounting member 24 are joined by brazing or the like.

Incidentally, the alloy CuW10 has a thermal conductivity of 180-200 (W/m·K), which is about 10 times as high as 17-18 (W/meK) being the thermal conductivity of the Covar. Besides, the Covar and the stainless steel are good in moldability and laser weldability.

Meanwhile, the inventor has revealed from various studies the fact that the distortion of the base 2 attendant upon the external temperature change of the semiconductor laser diode module becomes the most conspicuous at the central part of the thermo-electric-module 25. As stated before, the distortion of the base 2 occurs when the driving state of the thermo-electric-module 25 has changed in attendance on the external temperature change of the semiconductor laser diode module.

The inventor has determined the structure of the first embodiment on the basis of the studies. More specifically, the semiconductor laser diode module of the first embodiment is so constructed that the axis part 33, which connects the laser light emitting end face of the laser diode 1 at one end 31 thereof and the laser light receiving end 32 of the first optical fiber 4, is located on the end side of the thermo-electric-module 25 underlying the base 2, with respect to the central part C thereof in the direction of the optic-axis of the laser diode 1. Owing to this structure, the axis part 33 in the semiconductor laser diode module of the first embodiment is less susceptible to the distortion of the base 2 attendant upon the driving state change of the thermo-electric-module 25. Accordingly, the first optical fiber 4 and the laser diode 1 which constitute the semiconductor laser diode module of the first embodiment are restrained from undergoing a great positional deviation.

Consequently, the semiconductor laser diode module of the first embodiment becomes one of high power, good wavelength stability and low noise. Moreover, in the first embodiment, the wavelength lock is prevented from pulling out.

Besides, according to the first embodiment, the first optical fiber 4 is fixed by the plurality of fixation means 6 and 7 which are spaced in the lengthwise direction of this optical fiber 4. In the first embodiment, therefore, after the first optical fiber 4 has been fixed by the fixation means 6 nearer to the laser diode 1, the side of the first optical fiber 4 remoter from the laser diode 1 can be moved for concentering by utilizing the principle of a lever with a fulcrum at the fixed part and be thereafter fixed.

According to the first embodiment, therefore, the first optical fiber 4 can be more appropriately concentered and fixed relative to the laser diode 1 than in the case where, as shown in FIG. 6, the first optical fiber 4 is fixed to the base 2 at one point in its lengthwise-direction. Moreover, the first embodiment can reduce the noise of the semiconductor laser diode module still further and the value of the RIN of this module smaller, owing to the function of the isolator 53.

As described above, the semiconductor laser diode module of the first embodiment is a highly reliable one of low noise, high power and good wavelength stability. Therefore, when a Raman amplifier is consisted with the semiconductor laser diode module of the first embodiment as a pumping light source, it can be made an excellent Raman amplifier which is suited for wavelength division multiplexing (WDM) transmission.

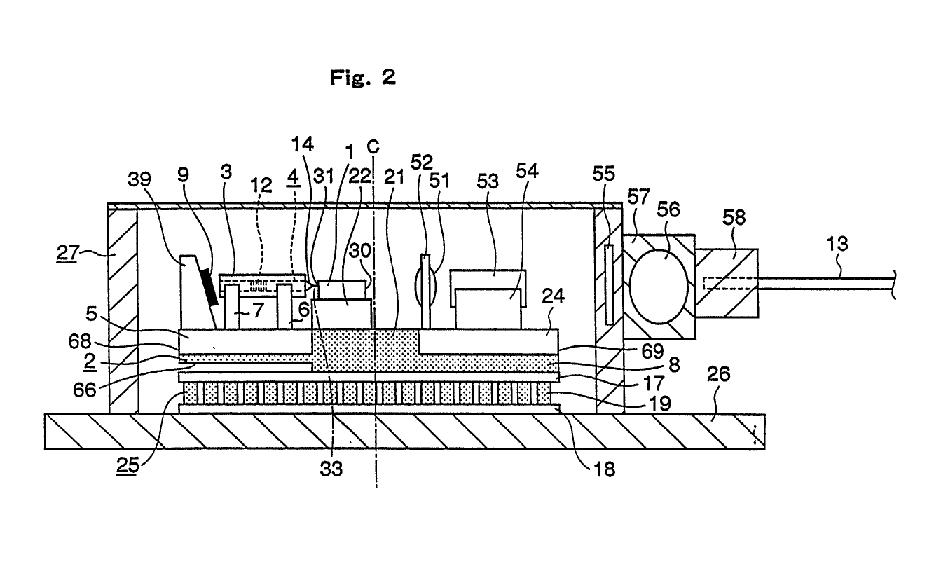

Shown in FIG. 2 is the second embodiment of the semiconductor laser module according to the present invention. The second embodiment is designed to be substantially similar to the first embodiment, and the same construction shall not be repeatedly described.

The feature of the second embodiment different from the first embodiment is that the lower surface 66 of a base 2 is held in a state out of contact with a thermo-electric-module 25. The non-contacting lower surface 66 extends from that part of the base 2 at which fixation means 6located nearest to a laser diode 1 is disposed, to that end 68 of the base 2 which is remoter from a second optical fiber 13.

The second embodiment is constructed as stated above, and can also achieve the same effects as those of the first embodiment.

Besides, in the second embodiment, the lower surface 66 of the base 2 extending from the part of the base 2 where the fixation means 6 is disposed, to the base end 68, is held in the state out of contact with the thermo-electric-module 25. Therefore, the second embodiment can more restrain a first optical fiber 4 from being decentered or made eccentric relative to the laser diode 1 under the influence of the distortion of the thermo-electric-module 25. Accordingly, the second embodiment becomes an excellent semiconductor laser diode module of high power, low noise and good wavelength stability.

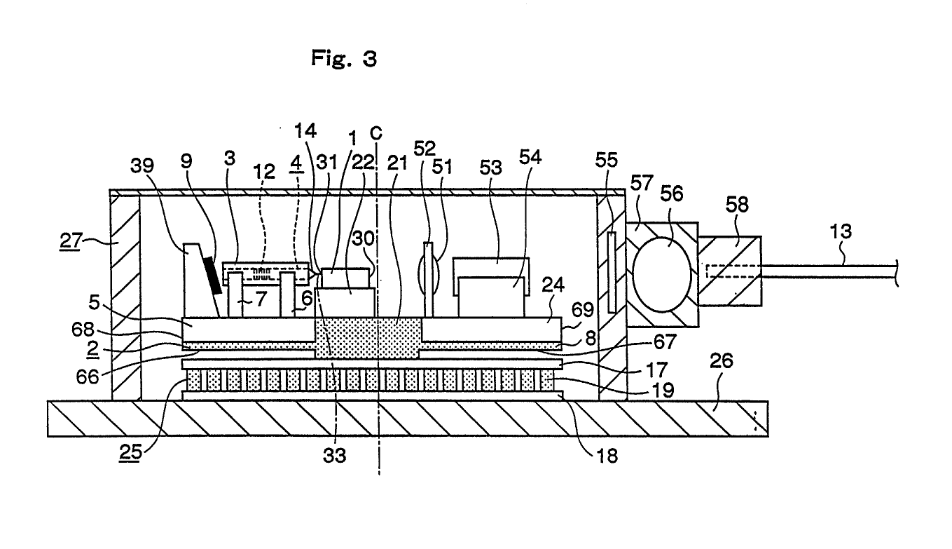

Shown in FIG. 3 is the third embodiment of the semiconductor laser diode module according to the present invention. The third embodiment is constructed to be substantially similar to the first or second embodiment, and the same structure shall not be repeatedly described.

The feature of the third embodiment different from the second embodiment is that the lower surface 67 of a base 2 as extends from the part of the base 2 where a collimating lens 51 is disposed, to the end 69 of the base 2 remoter from a first optical fiber 4, is held in a state out of contact with a thermo-electric-module 25.

The third embodiment is constructed as stated above, and can also achieve the same effects as those of the first or second embodiment.

Besides, in the third embodiment, the lower surface 67 of the base 2 extending from the part of the base 2 where collimating lens 51 is disposed, to the base end 69 remoter from the first optical fiber 4, is held in the state out of contact with the thermo-electric-module 25. Therefore, the third embodiment can restrain the collimating lens 51 and an isolator 53 from being decentered relative to a laser diode 1 by the distortion of the base 2. Accordingly, the third embodiment can also suppress lowering in the optical coupling efficiency between the laser diode 1 and a second optical fiber 13. Consequently, the third embodiment can be made a semiconductor laser module of still higher power and still lower noise.

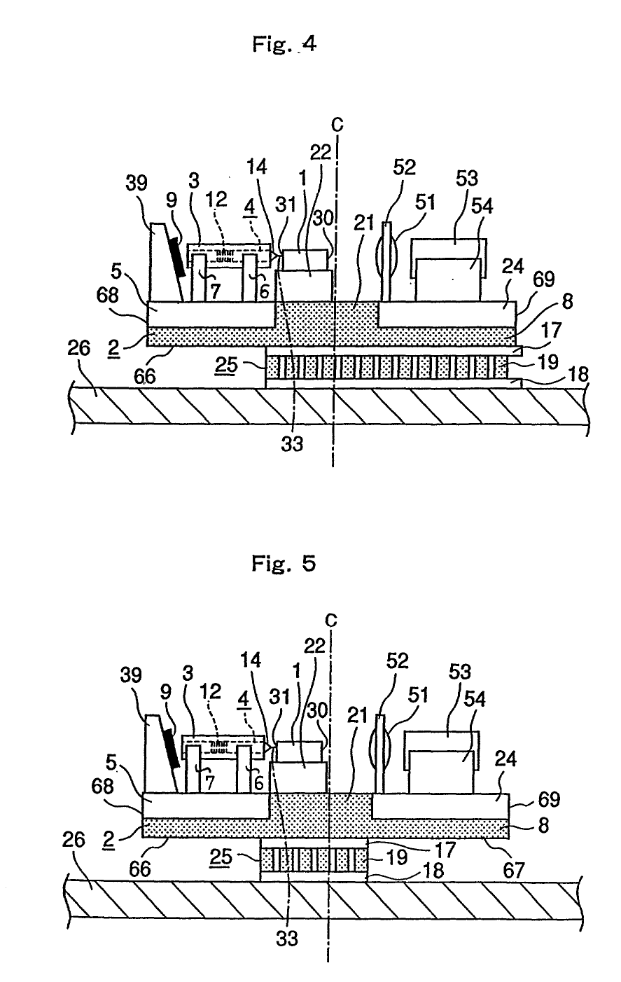

Incidentally, the present invention is not restricted to the foregoing embodiments, but it can adopt various modifications and alterations. By way of example, in each of the embodiments, the thermo-electric-module 25 is disposed so as to extend from one end (base end 68) of the base 2 to the other end (base end 69) thereof. In this regard, the semiconductor laser diode module of the present invention may well be so constructed that, as shown in FIG. 4 by way of example, a thermo-electric-module 25 is disposed so as to extend from under the LD bonding area 21 to the base end 69.

In this structure, the lower surface 66 of the base 2 as extends from the part of the base 2 where the fixation means 6 is disposed, to the base end 68, is held in a state out of contact with the thermo-electric-module 25. Also the semiconductor laser diode module of this structure can achieve the same effects as those of the second embodiment.

Besides, as shown in FIG. 5, the thermo-electric-module 25 may well be disposed only under the LD bonding area 21. In this structure, the lower surface 66 of the base 2 as extends from the part of the base 2 where the fixation means 6 is disposed, to the base end 68, is held in a state out of contact with the thermo-electric-module 25. In addition, the lower surface 67 of the base 2 as extends from the part of the base 2 where the collimating lens 51 is disposed, to the base end 69, is held in a state out of contact with the thermo-electric-module 25. Also the semiconductor laser diode module of this structure can achieve the same effects as those of the third embodiment.

Further, in each of the foregoing embodiments, the collimating lens 51, isolator 53 and condensing lens 56 are disposed between the second optical fiber 13 and the other end 30 of the laser diode 1. However, the collimating lens 51 or/and the isolator 53, for example, can be omitted. Besides, the semiconductor laser diode module may well be constructed by forming a fiber lens on the side of one end of the second optical fiber 13, instead of disposing the condensing lens 56. Also in this case, the fiber lens of the second optical fiber 13 may be an anamorphic lens such as in a wedge shape, or it may well be a fiber lens in a spherical tip shape.

Still further, in each of the foregoing embodiments, the fixation means 6 and 7 for fixing the first optical fiber 4 are located at the two points spaced in the lengthwise direction of the first optical fiber 4, but fixation means may be disposed in the appropriate number of at least one in the lengthwise direction of the first optical fiber 4.

Yet further, although the semiconductor laser diode module in each of the embodiments has been exemplified as being applied to the Raman amplifier, the semiconductor laser diode module of the present invention is not restricted to the pumping light source for the Raman amplifier. It has various applications for optical communications, such as the pumping light sources of amplifiers different from the Raman amplifier, and the light sources of signal lights.

What is claimed is:

1. A semiconductor laser diode module comprising:
a laser diode which emits laser lights;
a first optical fiber which is arranged on one end side of said laser diode in a state where it is optically coupled with said laser diode;
a second optical fiber which is arranged on the other end side of said laser diode in a state where it is optically coupled with said laser diode;
a base on which said laser diode and said first optical fiber are arranged and fixed;
a thermo-electric-module on which said base is mounted; and
a diffraction Bragg grating which is formed within said first optical fiber so as to feed the light of a set wavelength back to said laser diode;
wherein said laser diode and said first optical fiber are located relative to said thermo-electric-module so that a segment which connects a laser light emitting end face of said laser diode at one end thereof and a laser light receiving end of said first optical fiber may lie on an end side of said thermo-electric-module with respect to a central part thereof in an direction of an optic axis of said laser diode.

2. A semiconductor laser diode module according to claim 1, wherein:
said first optical fiber is fixed to said base by fixation means;
said fixation means is disposed in the number of at least one in a lengthwise direction of said first optical fiber; and
a lower surface of said base as extends from that part of said base at which said fixation means located nearest to said laser diode is disposed, to that end of said base which is remoter from said second optical fiber, is held in a state out of contact with said thermo-electric-module.

3. A semiconductor laser diode module according to claim 1, wherein:
at least one lens portion is disposed between said second optical fiber and that end face of said laser diode which opposes to said second optical fiber;
at least, the first lens portion located nearest to said laser diode is mounted on said base; and
a lower surface of said base as extends from that part of said base at which said first lens portion is disposed, to that end of said base which is remoter from said first optical fiber, is held in a state out of contact with said thermo-electric-module.

4. A Raman amplifier comprising:
a pumping light source which is formed by employing said semiconductor laser diode module according to claim 1.
